(19) United States
(12) Patent Application Publication
(10) Pub. No.: US 2017/0141277 A1
(43) Pub. Date: May 18, 2017

(54) ASSEMBLING STRUCTURES OF LIGHT EMITTING COMPONENTS

(71) Applicants: Shenzhen China Star Optoelectronics Technology Co., Ltd., Shenzhen, Guangdong (CN); WUHAN CHINA STAR OPTOELECTRONICS TECHNOLOGY CO., LTD, Wuhan, Hubei (CN)

(72) Inventors: Yan CHENG, Shenzhen, Guangdong (CN); Gege ZHOU, Shenzhen, Guangdong (CN)

(73) Assignees: Shenzhen China Star Optoelectronics Technology Co., Ltd., Shenzhen, Guangdong (CN); WUHAN CHINA STAR OPTOELECTRONICS TECHNOLOGY CO., LTD, Wuhan, Hubei (CN)

(21) Appl. No.: 14/905,787

(22) PCT Filed: Jun. 24, 2015
(86) PCT No.: PCT/CN2015/082200

§ 371 Date: Jan. 16, 2016

(30) Foreign Application Priority Data
May 27, 2015 (CN) 201510278736.X

(51) Int. Cl. H01L 33/62; H01L 49/02; H01L 25/075; H01L 33/60

(52) U.S. Cl. CPC H01L 33/62; H01L 33/60; H01L 28/20; H01L 25/0753

(57) ABSTRACT

The present invention discloses an assembling structure of light emitting components including a substrate, a light emitting component, and at least one connecting part. The light emitting component is arranged on the substrate, the light emitting component includes a first pin and a second pin embedded within the substrate, and at least one connecting part is embedded within the substrate. The connecting part electrically connects to the substrate. The connecting part connects the first pin and the second pin. Compared to the conventional solution, wherein the pins of the light emitting component and the lead are configured outside of the substrate, the light beams are prevented from being blocked by the components. Not only the light beams may be more uniform, but also the light beams are prevented from being absorbed by the lead.

CROSS REFERENCE

This application claims the priority of Chinese Patent Application No. 201510278736.X, entitled “Assembling structures of light emitting components”, filed on May 27, 2015, the disclosure of which is incorporated herein by reference in its entirety.

### FIELD OF THE INVENTION

The present invention relates to an electronic technology field, and more particularly to an assembly structure of light emitting components.

### BACKGROUND OF THE INVENTION

With respect to conventional light-emitting element assembly, the light emitting components are generally provided on the substrate. Two pins of the light-emitting elements are connected by wirings to provide electrical connection. However, since the lead is provided outside the substrate, when the light-emitting component emits light, a portion of the light beams may be absorbed by the lead, which results in a decreasing light extraction rate. Meanwhile, the lead may block the light beams from the light-emitting element, such that the emitted light is not uniform. In addition, as the two pins of the light-emitting element are provided outside of the substrate, the light beams from the light-emitting component maybe blocked, and thus the uniformity of the light beams emitted by the light emitting component may be affected.

### SUMMARY OF THE INVENTION

The technical issue that the embodiment of the present invention solves is to provide an assembling structure of light emitting component for reducing the optical absorption rate.

In one aspect, an assembling structure of light emitting components includes: a substrate, a light emitting component, and at least one connecting part, the light emitting component is arranged on the substrate, the light emitting component includes a first pin and a second pin embedded within the substrate, at least one connecting part is embedded within the substrate, and the at least one connecting part connects the first pin and the second pin so as to electrically connect the light emitting component to the substrate.

Wherein the substrate includes a receiving slot for receiving the first pin, the second pin and the connecting part.

Wherein the connecting part includes a first connecting portion a, a second connecting portion and a third connecting portion, the first connecting portion connects with the first pin, the third connecting portion connects with the second pin the second connecting portion connects between the first connecting portion and the third connecting portion, and the first connecting portion and the third connecting portion are perpendicular to the second connecting portion.

Wherein a conductive layer is arranged within the substrate to electrically connect the connecting part.

Wherein the assembling structure further includes two connecting part including a first connecting part and a second connecting part, one end of the first connecting part connects to the first pin, and the other end of the first connecting part connects to the conductive layer, one end of the second connecting part connects with the second pin, and the other end of the second connecting part electrically connects to the conductive layer.

Wherein the connecting part is a lead.

Wherein the assembling structure further includes a printed resistor electrically connected with the substrate, at least one of the printed circuit electrically connects to the substrate, and at least one printed resistor and the light emitting component are connected in parallel, and at least one of the printed resistor includes a first reflective layer and a second reflective layer stacked together.

In another aspect, an assembling structure of light emitting components includes: a substrate, a light emitting component, a lead, and a reflective coating layer, the light emitting component is arranged on the substrate, the light emitting component includes a first pin and a second pin opposite to each other, the first pin and the second pin are configured outside of the substrate, and the reflective coating layer is coated on the lead.

Wherein the reflective coating layer is a reflective resin layer.

Wherein the assembling structure further includes a printed resistor electrically connected with the substrate, at least one of the printed circuit electrically connects to the substrate, and at least one printed resistor and the light emitting component are connected in parallel, and at least one of the printed resistor includes a first reflective layer and a second reflective layer stacked together.

In view of the above, the first pin, the second pin, and the connecting part of the light emitting component are embedded within the substrate. The connecting part connects the first pin and the second pin to provide electrical connection. Compared to the conventional solution, wherein the pins of the light emitting component and the lead are configured outside of the substrate, the light beams are prevented from being blocked by the components. Not only the light beams may be more uniform, but also the light beams are prevented from being absorbed by the lead. Thus, the optical absorbing rate is decreased so as to guarantee the lighting effect of the light emitting component.

The assembling structure of light emitting components includes the lead coated with the reflective coating layer. The optical absorbing rate is decreased so as to guarantee the lighting effect of the light emitting component. The assembling structure of light emitting components includes the advantages such as simple structure and may be easily assembled.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a schematic view of the assembling structure of light emitting components in accordance with a first embodiment.

FIG. 2 is a schematic view showing the details of FIG. 1.

FIG. 3 is a schematic view of the assembling structure of light emitting components in accordance with a second embodiment.

FIG. 4 is a schematic view of the assembling structure of light emitting components in accordance with a third embodiment.

### DETAILED DESCRIPTION OF PREFERRED EMBODIMENTS

Embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained, should be considered within the scope of protection of the present invention.

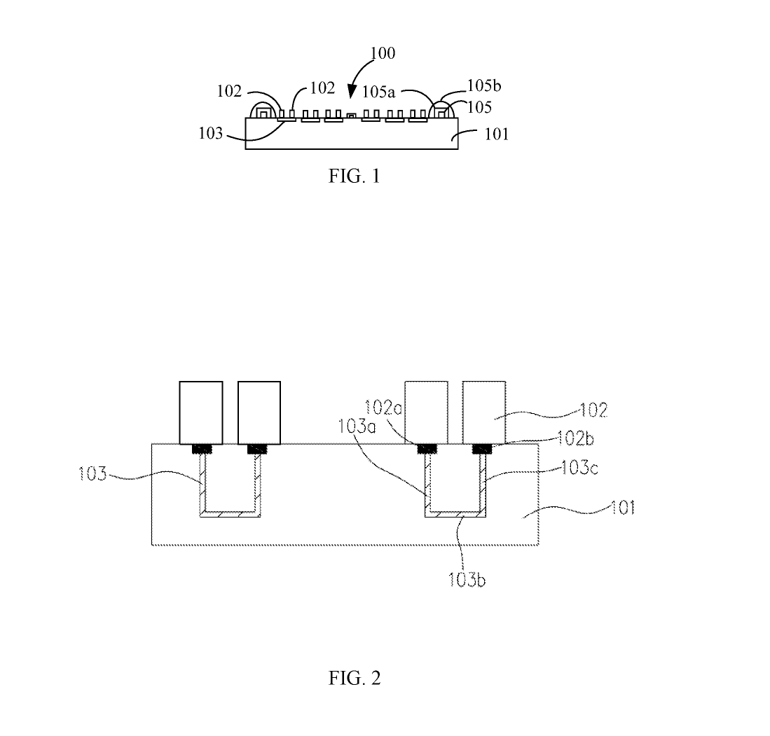

Referring to FIGS. 1 and 2, the assembling structure of light emitting components 100 includes a substrate 101, a light emitting component 102, and at least one connecting part 103. The light emitting component 102 is arranged on the substrate 101. The light emitting component 102 includes a first pin 102a and a second pin 102b embedded within the substrate 101. At least one connecting part 103 is embedded within the substrate 101, and at least one connecting part 103 connects the first pin 102a and the second pin 102b.

Within the assembling structure of light emitting components 100, the first pin 102a and the second pin 102b of the light emitting component 102 are embedded within the substrate 101. At the same time, the connecting part 103 is also embedded within the substrate 101, and the connecting part 103 connects the first pin 102a and the second pin 102b. As such, when the light emitting component 102 provides the electrical connection, the light beams emitted from the light emitting component 102 are prevented from being blocked by the first pin 102a, the second pin 102b, and the connecting part 103, which ensures the lighting effect of the light emitting component 102.

In the embodiment, the substrate 101 is a rectangular-shaped plate. The substrate 101 includes a receiving slot (not shown) for receiving the first pin 102a, the second pin 102b, and the connecting part 103. Specifically, the number of the receiving slot may be one, two, or more than two. Preferably, the substrate 101 includes one receiving slot, and the first pin 102a, the second pin 102b, and the connecting part 103 are embedded within the receiving slot.

In the embodiment, the number of the light emitting component 102 may be one, two, or more than two. Specifically, the number of the light emitting component 102 may be configured in accordance with the lighting effect of the assembling structure of light emitting components 100.

The first pin 102a and the second pin 102b are arranged to be opposite to each other. The first pin 102a is a positive pin, and the second pin 102b is a negative pin. It can be understood that, in other embodiments, the first pin 102a may be the negative pin, and the second pin 102b may be the positive pin.

At least one connecting part 103 electrically connects with the substrate 101. In the embodiment, the number of the connecting part 103 corresponds to the number of the light emitting component 102. Preferably, when only one light emitting component 102 is configured, only one connecting part 103 is configured. The connecting part 103 is of the “ [symbol] ”-shaped structure. The connecting part 103 includes a first connecting portion 103a, a second connecting portion 103b, and a third connecting portion 103c. The first connecting portion 103a connects with the first pin 102a, the third connecting portion 103c connects with the second pin 102b such that the light emitting component 102 is electrically connected with the substrate 101. The second connecting portion 103b connects between the first connecting portion 103a and the third connecting portion 103c. In addition, the first connecting portion 103a and the third connecting portion 103c are perpendicular to the second connecting portion 103b such that the first connecting portion 103a is connected with the third connecting portion 103c. Specifically, a conductive layer may be arranged within the substrate 101. The second connecting portion 103b is arranged within the conductive layer such that the second connecting portion 103b is electrically connected with the conductive layer. The second connecting portion 103b connects the first connecting portion 103a and the third connecting portion 103c, and the first connecting portion 103a and the third connecting portion 103c respectively connects to the first pin 102a and the second pin 102b. In this way, the first pin 102a and the second pin 102b are electrically connected.

Further, in the embodiment, the connecting part 103 is a lead. The connecting part 103 is fixed and then is embedded within the receiving slot of the substrate 101. As such, the light emitting component 102 and the substrate 101 are electrically connected, and the light beams from the light emitting component 102 are prevented from being absorbed or blocked by the connecting part 103, which guarantees the lighting effect of the light emitting component 102.

It can be understood that, in the embodiment, the assembling structure of light emitting components 100 further includes a printed resistor 105 electrically connected with the substrate 101. Specifically, two printed resistors 105 are provided. The printed resistors 105 are symmetrical with respect to a center of the substrate 101, and are arranged at two lateral sides of the light emitting component 102. The printed resistor 105 and the light emitting component 102 are connected in parallel so as to balance and stabilize the current.

The printed resistor 105 includes a first reflective layer 105a and a second reflective layer 105b stacked together such that the light beams from the light emitting component 102 passing through the printed resistor 105 may be reflected by the first reflective layer 105a and the second reflective layer 105b. In this way, the light beams from the light emitting component 102 are prevented from being blocked by the printed resistor 105. At the same time, the optical absorbing rate of the printed resistor 105 may be reduced.

In one embodiment, within the assembling structure of light emitting components 100, the first pin 102a and the second pin 102b of the light emitting component 102 are

In the first embodiment, within the assembling structure of light emitting components 100, the first pin 102a and the second pin 102b of the 102 of the 102 are embedded within the substrate 101. At the same time, the connecting part 103 connects the first pin 102a and the second pin 102b, and the connecting part 103 is embedded within the substrate 101. In this way, the first pin 102a, the second pin 102b, and the connecting part 103 are prevented from causing the issue of blocking the light beams from the light emitting component 102 for the reason that the components are configured outside of the substrate 101. Thus, the optical absorbing rate is decreased, and the lighting effect of the light emitting component 102 is guaranteed.

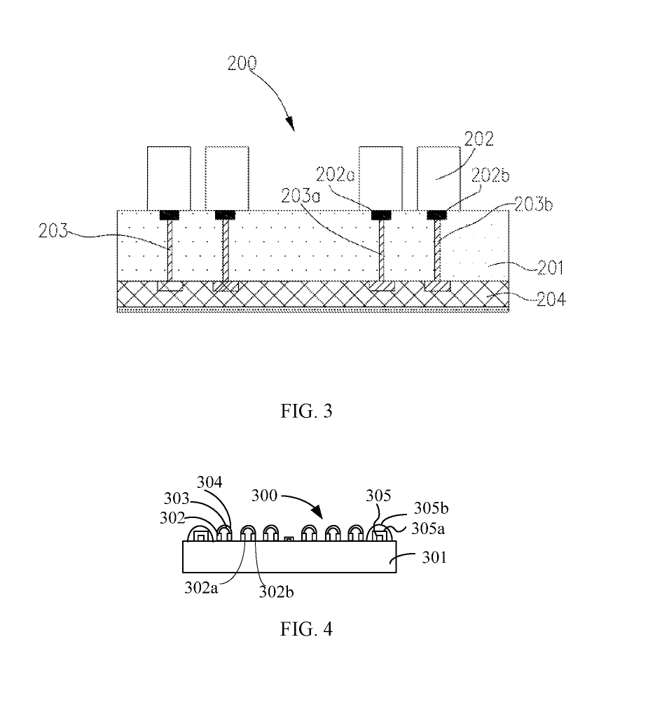

Referring to FIG. 3, in the second embodiment, the assembling structure of light emitting components 200 includes a substrate 201, a light emitting component 202, and at least one connecting part 203. The light emitting component 202 includes a first pine 202a and a second pin 202b opposite to each other. The first pine 202a and the second pin 202b are embedded within the substrate 201. The at least one connecting part 203 connects the first pine 202a and the second pin 202b, and the at least one connecting part 203 is embedded within the substrate 201.

The difference between the assembling structure of light emitting components 200 in the second embodiment and the assembling structure of light emitting components 100 in the first embodiment resides in that:

The assembling structure of light emitting components 200 further includes a conductive layer 204 embedded within the substrate 201. The conductive layer 204 is configured for electrically connecting with the connecting part 203. In the embodiment, conductive layer 204 is embedded at one side far away from the light emitting component 202. The thickness of the conductive layer 204 may be configured in accordance with real scenario.

Two of the connecting parts 203 are configured, which are respectively a first connecting part 203a and a second connecting part 203b. The first connecting part 203a is of an inversed-T-shaped structure. One end of the first connecting part 203a connects to the first pin 202a, and the other end of the first connecting part 203a connects to the conductive layer 204 so as to electrically connect the light emitting component 202 and the second display portion 20a. The second connecting part 203b is also of the inversed-T-shaped structure. One end of the second connecting part 203b connects with the second pin 202b, and the other end of the second connecting part 203b electrically connects with the conductive layer 204 so as to electrically connect the light emitting component 202 and the substrate 201. Further, the light emitting component 202 may emit the lights.

In the second embodiment, the assembling structure of light emitting components 200 includes the conductive layer 204 within the substrate 201. The first connecting part 203a connects the first pine 202a and the conductive layer 204. Also, the second connecting part 203b connects the second pin 202b and the conductive layer 204 so as to electrically connect the light emitting component 202 and the substrate 201. In addition, as the first pine 202a, the second pin 202b, the first connecting part 203a, the 203b, the 203b are embedded within the substrate 201. In this way, the light beams from the light emitting component 202 are prevented from being blocked by the components. Thus, the optical absorbing rate is decreased, and the lighting effect of the light emitting component 102 is guaranteed.

FIG. 4 is a schematic view of the assembling structure of light emitting components in accordance with a third embodiment.

The difference between the assembling structure of light emitting components 300 in the third embodiment and the assembling structure of light emitting components 200 in the second embodiment resides in that:

The assembling structure of light emitting components 300 includes a substrate 301, a light emitting component 302, a lead 303, and a reflective coating layer 304. The light emitting component 302 is arranged on the substrate 301. The light emitting component 302 includes a first pin 302a and a second pin 302b opposite to each other. The first pin 302a and the second pin 302b are arranged outside of the substrate 301. Two ends of the lead 303 respectively connect to the first pin 302a and the second pin 302b. in addition, the lead 303 is arranged outside of the substrate 301 so as to connect the light emitting component 302 and the substrate 301. As such, the light emitting component 302 may emit the lights normally. The reflective coating layer 304 is coated on the lead 303.

In the embodiment, the reflective coating layer 304 is a reflective resin layer. The lead 303 is coated with the reflective coating layer 304 such that the light beams from the light emitting component 302 are reflected when the light beams pass through the lead 303. In this way, the light beams from the light emitting component 302 are prevented from being blocked by the lead 303, and the optical absorbing rate of the lead 303 is decreased. In this way, the lighting effect of the light emitting component 302 is guaranteed.

It can be understood that in the embodiment, the

It can be understood that, in the embodiment, the assembling structure of light emitting components 300 further includes a printed resistor 305 electrically connected with the substrate 301. Specifically, two printed resistors 305 are provided. The printed resistors 305 are symmetrical with respect to a center of the substrate 301, and are arranged at two lateral sides of the light emitting component 102. The printed resistor 305 and the light emitting component 302 are connected in parallel so as to balance and stabilize the current.

The printed resistor 305 includes a first reflective layer 305a and a second reflective layer 305b stacked together such that the light beams from the light emitting component 302 passing through the printed resistor 305 may be reflected by the first reflective layer 305a and the second reflective layer 305b. In this way, the light beams from the light emitting component 302 are prevented from being blocked by the printed resistor 305. At the same time, the optical absorbing rate of the printed resistor 305 may be reduced.

In the third embodiment, the lead 303 is coated with the reflective coating layer 304 such that the reflective coating layer 304 may prevented the light beams from the light emitting component 302 from being blocked by the lead 303. At the same time, the optical absorbing rate of the lead 303 may be reduced. Thus, the light beams are uniform and the lighting effect of the light emitting component 302 is guaranteed.

In view of the above, the first pin, the second pin, and the connecting part of the light emitting component are embedded within the substrate. The connecting part connects the first pin and the second pin to provide electrical connection. Compared to the conventional solution, wherein the pins of the light emitting component and the lead are configured outside of the substrate, the light beams are prevented from being blocked by the components. Not only the light beams may be more uniform, but also the light beams are prevented from being absorbed by the lead. Thus, the optical absorbing rate is decreased so as to guarantee the lighting effect of the light emitting component.

The assembling structure of light emitting components includes the lead coated with the reflective coating layer. The optical absorbing rate is decreased so as to guarantee the lighting effect of the light emitting component. The assembling structure of light emitting components includes the advantages such as simple structure and may be easily assembled.

Above are embodiments of the present invention, which does not limit the scope of the present invention. Any modifications, equivalent replacements or improvements within the spirit and principles of the embodiment described above should be covered by the protected scope of the invention.

What is claimed is:

1. An assembling structure of light emitting components, comprising:
a substrate, a light emitting component, and at least one connecting part, the light emitting component is arranged on the substrate, the light emitting component comprises a first pin and a second pin embedded within the substrate, at least one connecting part is embedded within the substrate, and the at least one connecting part connects the first pin and the second pin so as to electrically connect the light emitting component to the substrate.

2. The assembling structure of light emitting components as claimed in claim 1, wherein the substrate comprises a receiving slot for receiving the first pin, the second pin and the connecting part.

3. The assembling structure of light emitting components as claimed in claim 1, wherein the connecting part comprises a first connecting portion a, a second connecting portion and a third connecting portion, the first connecting portion connects with the first pin, the third connecting portion connects with the second pin the second connecting portion connects between the first connecting portion and the third connecting portion, and the first connecting portion and the third connecting portion are perpendicular to the second connecting portion.

4. The assembling structure of light emitting components as claimed in claim 1, wherein a conductive layer is arranged within the substrate to electrically connect the connecting part.

5. The assembling structure of light emitting components as claimed in claim 4, wherein the assembling structure further comprises two connecting part comprising a first connecting part and a second connecting part,
one end of the first connecting part connects to the first pin, and the other end of the first connecting part connects to the conductive layer, one end of the second connecting part connects with the second pin, and the other end of the second connecting part electrically connects to the conductive layer.

6. The assembling structure of light emitting components as claimed in claim 1, wherein the connecting part is a lead.

7. The assembling structure of light emitting components as claimed in claim 1, wherein the assembling structure further comprises a printed resistor electrically connected with the substrate, at least one of the printed circuit electrically connects to the substrate, and at least one printed resistor and the light emitting component are connected in parallel, and at least one of the printed resistor comprises a first reflective layer and a second reflective layer stacked together.

8. An assembling structure of light emitting components, comprising:
a substrate, a light emitting component, a lead, and a reflective coating layer, the light emitting component is arranged on the substrate, the light emitting component comprises a first pin and a second pin opposite to each other, the first pin and the second pin are configured outside of the substrate, and the reflective coating layer is coated on the lead.

9. The assembling structure of light emitting components as claimed in claim 8, wherein the reflective coating layer is a reflective resin layer.

10. The assembling structure of light emitting components as claimed in claim 8, wherein the assembling structure further comprises a printed resistor electrically connected with the substrate, at least one of the printed circuit electrically connects to the substrate, and at least one printed resistor and the light emitting component are connected in parallel, and at least one of the printed resistor comprises a first reflective layer and a second reflective layer stacked together.
